(19) United States
(12) Patent Application Publication
(10) Pub. No.: US 2025/0311118 A1
(43) Pub. Date: Oct. 2, 2025

(54) ELECTRONIC DEVICE

(71) Applicant: DENSO CORPORATION, Kariya-city (JP)

(72) Inventors: Ryohei WAKUDA, Kariya-city (JP); Hiroki CHITAKA, Kariya-city (JP)

(21) Appl. No.: 19/078,733

(22) Filed: Mar. 13, 2025

(30) Foreign Application Priority Data
Mar. 26, 2024 (JP) 2024-050362

(51) Int. Cl. H05K 5/00; H05K 7/14

(52) U.S. Cl. CPC H05K 5/006; H05K 7/1418

(57) ABSTRACT

An electronic device includes a first circuit board, a second circuit board, a first housing member, and a second housing member. The first housing member includes a first positioning part having a first board positioning portion that positions the first housing member and the first circuit board, and a first housing positioning portion that positions the first housing member and the second housing member. The second housing member includes a second positioning part having a second board positioning portion that positions the second housing member and the second circuit board, and a second housing positioning portion that engages with the first housing positioning portion to position the first housing member and the second housing member. The first board positioning portion, the first housing positioning portion, the second board positioning portion, and the second housing positioning portion are arranged on a same straight line.

### CROSS REFERENCE TO RELATED APPLICATION

The present application claims the benefit of priority from Japanese Patent Application No. 2024-050362 filed on Mar. 26, 2024. The entire disclosures of the above application are incorporated herein by reference.

### TECHNICAL FIELD

The present disclosure relates to an electronic device.

### BACKGROUND

There is an electronic device having an upper printed wiring board and a lower printed wiring board that are stacked to face each other. In such an electronic device, a support body may be used for stacking the lower printed wiring board and the upper printed wiring board at a preset interval, which is predetermined.

The lower printed wiring board may be provided with a pin header. The upper printed wiring board may be provided with a connector. The support body may be integrally molded to have a screw hole into which a screw is screwed from the back side of the lower printed wiring board, and a protrusion onto which a nut is screwed after being inserted into a mounting hole of the upper printed wiring board. In such a configuration, if the position of the mounting hole of the upper printed wiring board is matched to an engagement position of the pin header and the connector, the pin header and the connector can be aligned with each other by inserting the protrusion into the mounting hole of the upper printed wiring board.

### SUMMARY

An electronic device according to an aspect includes a first circuit board, a second circuit board, a first housing member, and a second housing member. The first housing member is disposed between the first circuit board and the second circuit board. The second housing member is disposed between the first circuit board and the second circuit board. The first housing member includes a first positioning part having a first board positioning portion that positions the first housing member and the first circuit board, and a first housing positioning portion that positions the first housing member and the second housing member. The second housing member includes a second positioning part having a second board positioning portion that positions the second housing member and the second circuit board, and a second housing positioning portion that engages with the first housing positioning portion to position the first housing member and the second housing member. The first board positioning portion, the first housing positioning portion, the second board positioning portion, and the second housing positioning portion are arranged on a same straight line.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a perspective view showing a schematic configuration of an electronic device;

FIG. 2 is a cross-sectional view of the semiconductor device taken along a line II-II of FIG. 1;

FIG. 3 is a cross-sectional view taken along a line III-III in FIG. 1;

FIG. 4 is a perspective view showing a schematic configuration on a first circuit board side;

FIG. 5 is a perspective view showing a schematic configuration on a mounting surface side of a first housing member;

FIG. 6 is a perspective view showing a schematic configuration on a facing surface side of the first housing member;

FIG. 7 is a perspective view showing a schematic configuration on a second circuit board side;

FIG. 8 is a perspective view showing a schematic configuration on a mounting surface side of a second housing member;

FIG. 9 is a perspective view showing a schematic configuration on a facing surface side of the second housing member;

FIG. 10 is a cross-sectional view showing a schematic configuration of a positioning part of the electronic device;

FIG. 11 is an exploded perspective view showing a schematic configuration of an electronic device; and

FIG. 12 is a cross-sectional view showing a schematic configuration of a positioning part in a modified example.

### DETAILED DESCRIPTION

As a related art, an electronic device may be configured to have a first housing member on which a first circuit board is mounted and a second housing member on which a second circuit board is mounted, and to arrange the first and second housing members to be located between the first circuit board and the second circuit board. In such a configuration of the electronic device, even if a support body is used, it is difficult to accurately position the first circuit board and the second circuit board relative to each other due to the housing members.

The present disclosure provides an electronic device in which circuit boards can be positioned accurately.

According to an aspect of the present disclosure, an electronic device includes a first circuit board, a second circuit board, a first housing member, and a second housing member. The first housing member is disposed between the first circuit board and the second circuit board, and the first circuit board is attached to the first housing member. The second housing member is disposed between the first circuit board and the second circuit board, and the first housing member and the second circuit board are attached to the second housing member. The first housing member includes a first positioning part. The first positioning part has a first board positioning portion that positions the first housing member and the first circuit board, and a first housing positioning portion that positions the first housing member and the second housing member. The second housing member includes a second positioning part. The second positioning part has a second board positioning portion that positions the second housing member and the second circuit board, and a second housing positioning portion that engages with the first housing positioning portion to position the first housing member and the second housing member. The first board positioning portion, the first housing positioning portion, the second board positioning portion, and the second housing positioning portion are arranged on a same straight line.

As described above, the electronic device includes the first positioning part that has the first board positioning portion and the first housing positioning portion, and the second positioning part that has the second board positioning portion and the second housing positioning portion. Therefore, in the electronic device, the first housing member and the first circuit board are positioned relative to each other, the first housing member and the second housing member are positioned relative to each other, and the second housing member and the second circuit board are positioned relative to each other. In other words, in the electronic device, the first circuit board and the second circuit board can be positioned relative to each other.

Further, in the electronic device, since the first board positioning portion, the first housing positioning portion, the second board positioning portion, and the second housing positioning portion are arranged on the same straight line, an accumulation of tolerances thereof can be minimized. Therefore, in the electronic device, the first circuit board and the second circuit board can be positioned accurately.

Hereinafter, multiple embodiments of the present disclosure will be described with reference to the drawings. Hereinafter, three directions perpendicular to each other are denoted as an X direction, a Y direction, and a Z direction.

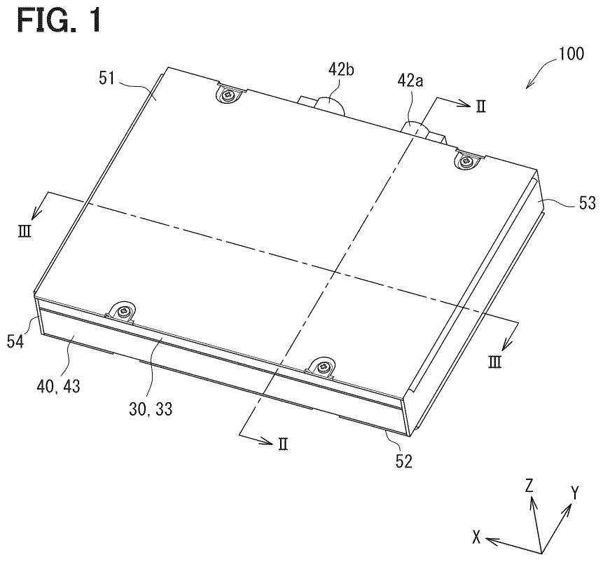

An electronic device 100 according to the present embodiment will be described with reference to FIGS. 1 to 10. The electronic device 100 mainly comprises a first circuit board 10, a second circuit board 20, a first housing member 30, and a second housing member 40. In the present embodiment, as an example, the electronic device 100 includes a first cover 51, a second cover 52, a third cover 53, and a fourth cover 54. The electronic device 100 is configured to cool the first circuit board 10 and the second circuit board 20 with cooling water CW1. The cooling water CW1 corresponds to a liquid refrigerant.

The electronic device 100 is configured so as to be mountable on a mobile object such as a vehicle. For example, the electronic device 100 can be applied to an electronic control unit. Further, the electronic device 100 can also be applied to an integrated control unit in which multiple functions are integrated. Furthermore, the electronic device 100 can also be applied to an electronic control unit for automatic driving. Each component of the electronic device 100 will be described hereinafter.

### First Circuit Board

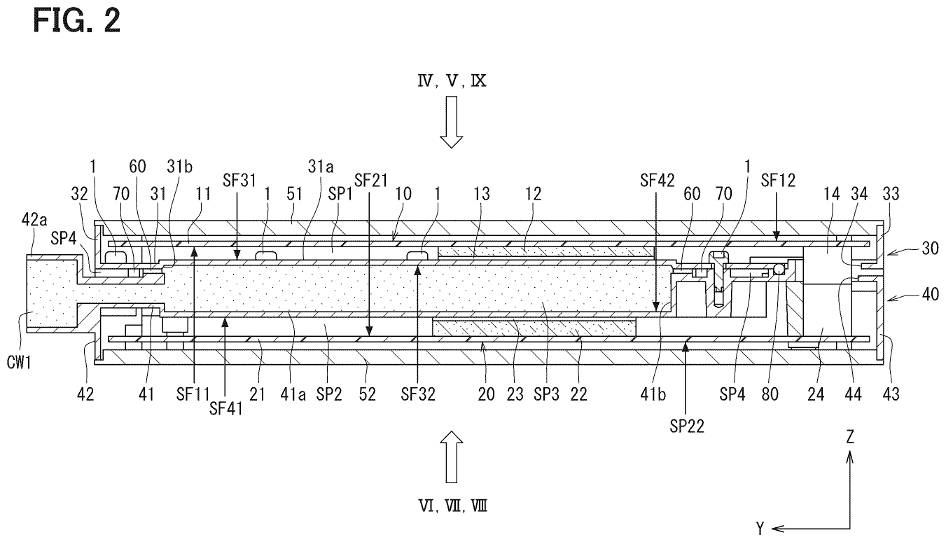

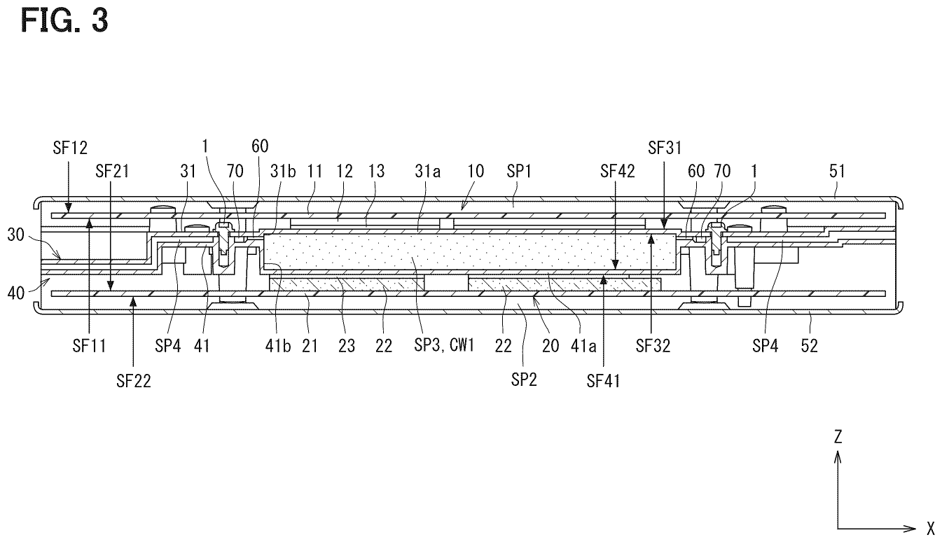

As shown in FIGS. 2 and 3, the first circuit board 10 includes a wiring board 11, a mounted component 12, a heat conductive member 13, a first connector 14, and the like. The wiring board 11 includes, for example, an electrically insulating base material such as resin, and conductive wirings such as copper wirings. The wiring board 11 is a so-called printed wiring board. The wiring board 11 has a mounting surface SF11 on which the mounted component 12 is mounted, and a back surface SF12 opposite the mounting surface SF11. The wiring board 11 is disposed along an XY plane including the X direction and the Y direction.

The mounted component 12 is mounted on the mounting surface SF11. The mounted component 12 is electrically connected to the wiring of the wiring board 11. The mounted component 12 may be a SoC or the like. Therefore, the first circuit board 10 is configured so that the mounted component 12 executes arithmetic processing. The first circuit board 10 can also be regarded as an electronic control unit. “SoC” is an abbreviation for System on a Chip.

The wiring board 11 may have circuit components, other than the mounted component 12, mounted thereon. The number of the mounted components 12 mounted on the wiring board 11 is not particularly limited. The wiring board 11 may have circuit components on the back surface SF12.

The mounted component 12 is a circuit component that generates heat when in operation. The mounted component 12 correspond to a heat generation component. Therefore, in the present embodiment, an example in which the heat conductive member 13 is provided on the mounted component 12 is adopted. The mounted component 12 is disposed to face a mounting surface SF31 of a first housing member 30, which will be described later. The mounted component 12 is mounted on the first housing member 30 via the heat conductive member 13. The heat conductive member 13 is in contact with the first housing member 30.

The heat conductive member 13 is a member for lowering a thermal resistance between the mounted component 12 and the first housing member 30. The heat conductive member 13 may be a heat dissipating gel or a heat dissipating sheet. The heat conductive member 13 will be also referred to as a thermal interface material.

The first connector 14 is mounted on the mounting surface SF11. The first connector 14 is electrically connected to the wiring of the wiring board 11. The first connector 14 is an interface for electrically connecting the first circuit board 10 and the second circuit board 20.

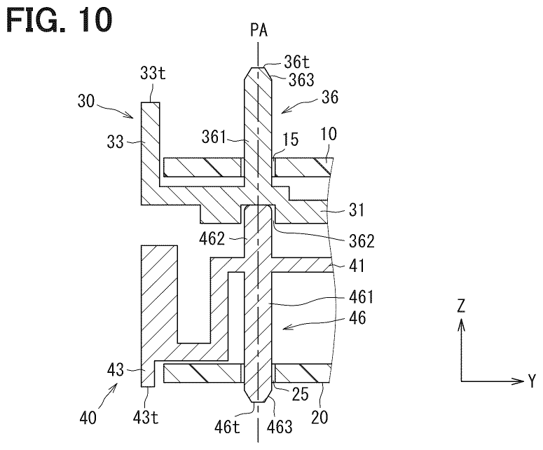

As shown in FIG. 10, the first circuit board 10 is formed with a positioning hole 15. The positioning hole 15 is provided for positioning the first circuit board 10 and the first housing member 30. It can be said that the positioning hole 15 is provided for positioning the first circuit board 10 and the second circuit board 20.

The positioning hole 15 is a through hole that penetrates the wiring board 11 from the mounting surface SF11 to the back surface SF12. When the first circuit board 10 is attached to the first housing member 30, a protrusion 361 is inserted into the positioning hole 15. The positioning hole 15 has a shape corresponding to the protrusion 361. In the present embodiment, as an example, the positioning hole 15 has a circular shape.

In the present embodiment, as an example, the first circuit board 10 has two positioning holes 15 at two locations. However, the number of the positioning holes 15 is not limited to two. The number of the positioning holes 15 is the same as the number of the protrusions 361. The protrusion 361 and the positioning thereof will be described later.

### Second Circuit Board

As shown in FIGS. 2 and 3, the second circuit board 20 includes a wiring board 21, a mounted component 22, a heat conductive member 23, a second connector 24, and the like. The second circuit board 20 has a similar structure to the first circuit board 10. In other words, components with the same names but different reference numerals are similar to the components of the first circuit board 10.

The mounted component 22 is disposed to face a mounting surface SF41 of a second housing member 40, which will be described later. The mounted component 22 is mounted on the second housing member 40 via the heat conductive member 23.

The second circuit board 20 is electrically connected to the first circuit board 10 by connecting the second connector 24 and the first connector 14 to each other. In other words, the first connector 14 and the second connector 24 are configured as a pair. For example, the second connector 24 and the first connector 14 may be configured so that one of which has a conductive pin and the other has a conductive socket. When the second connector 24 and the first connector 14 are attached to each other, the conductive pin and the conductive socket are electrically connected. The first connector 14 can also be referred to as a first board-to-board connector. The second connector 24 can also be referred to as a second board-to-board connector. The first connector 14 and the second connector 24 are so-called B-to-B connectors. The first connector 14 and the second connector 24 can also be referred to as board-connecting connectors or board-to-board connectors.

The second circuit board 20 differs from the first circuit board 10 in the number of the mounted component 22 and the contents of the arithmetic processing of the mounted component 22. The wiring board 21 has a mounting surface SF21 on which the mounted component 22 is mounted, and a back surface SF22 opposite the mounting surface SF21. The mounted component 22 corresponds to a heat generation component.

Further, as shown in FIG. 10, the second circuit board 20 is formed with a positioning hole 25. The positioning hole 25 is provided for positioning the second circuit board 20 and the second housing member 40. It can be said that the positioning hole 25 is provided for positioning the first circuit board 10 and the second circuit board 20.

The positioning hole 25 is a through hole that penetrates the wiring board 21 from the mounting surface SF21 to the back surface SF22. When the second circuit board 20 is attached to the second housing member 40, a protrusion 461 is inserted into the positioning hole 25. The positioning hole 25 has a shape corresponding to the protrusion 461. In the present embodiment, as an example, the positioning hole 25 has a circular shape.

In the present embodiment, as an example, the second circuit board 20 has two positioning holes 25 at two locations. However, the number of the positioning holes 25 is not limited to two. The number of the positioning holes 25 is the same as the number of the protrusions 461. The protrusion 461 will be described later. In order to distinguish the positioning holes 15 and the positioning holes 25 from each other, the positioning holes 15 can also be referred to as a first positioning hole and the positioning holes 25 can also be referred to as a second positioning hole.

The electronic device 100 may also be configured such that either of the first circuit board 10 or the second circuit board 20 is provided with the heat generation component. Hereinafter, when there is no need to distinguish the first circuit board 10 and the second circuit board 20 from each other, the first circuit board 10 and the second circuit board 20 will be collectively referred to as the circuit boards 10 and 20.

### Housing

As shown in FIGS. 1, 2 and 3, the housing includes a first housing member 30 and a second housing member 40. The housing also includes a first cover 51, a second cover 52, a third cover 53, and a fourth cover 54. The housing is formed by assembling the first housing member 30, the second housing member 40, the first cover 51, the second cover 52, the third cover 53, and the fourth cover 54.

First, the first housing member 30 will be described with reference to FIGS. 2 to 6. As shown in FIGS. 2, 3 and 4, the first housing member 30 is a member that accommodates the first circuit board 10. It can be said that the first housing member 30 is a member on which the first circuit board 10 is mounted. Therefore, the first housing member 30 can also be referred to as a mounted member or a first mounted member. Moreover, the first housing member 30 is disposed between the first circuit board 10 and the second circuit board 20, and the first circuit board 10 is attached to the first housing member 30.

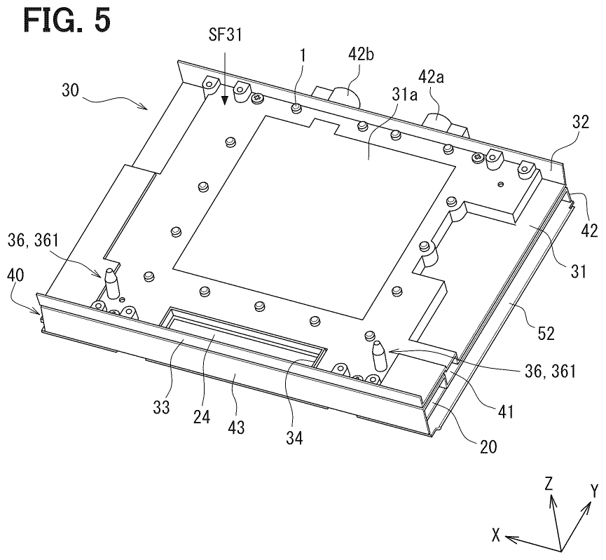

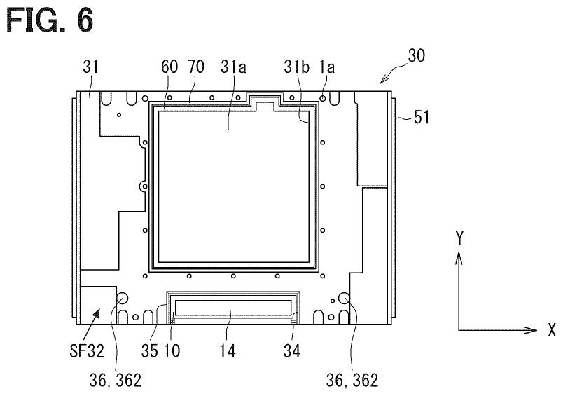

As shown in FIGS. 5 and 6, the first housing member 30 includes a base portion 31 and side walls 32 and 33. The base portion 31 has a mounting surface SF31 on which the first circuit board 10 is mounted, and a facing surface SF32 which is the surface opposite to the mounting surface SF31. The facing surface SF32 is a surface that faces the second housing member 40 when the first housing member 30 and the second housing member 40 are attached to each other. The side walls 32 and 33 correspond to first side walls.

The base portion 31 has the side walls 32 and 33 at both ends in the Y direction. The side walls 32 and 33 protrude in the Z direction from the base portion 31. The side walls 32 and 33 are disposed to extend along the X direction. The first housing member 30 has a first accommodation section SP1 that accommodates the first circuit board 10 in an area provided between the side wall 32 and the side wall 33. The first accommodation section SP1 is a facing area of the mounting surface SF31 and is an area between the side wall 32 and the side wall 33. In addition, it can be said that the first housing member 30 has the side walls 32 and 33 that are disposed on a periphery of the first circuit board 10 when the first circuit board 10 is accommodated in the first housing member 30. As shown in FIG. 10, the tip portion of the side wall 33 will be also referred to as a side wall end 33t.

When the first circuit board 10 is accommodated in the first housing member 30, the mounting surface SF11 faces the mounting surface SF31. On the other hand, the back surface SF12 is exposed. Therefore, the first cover 51 is attached to the first housing member 30 in the facing area of the mounting surface SF31. In other words, the first cover 51 is attached to the first housing member 30 so as to cover the back surface SF12.

Further, the third cover 53 and the fourth cover 54 are attached to the first housing member 30 at the ends of the base portion 31, the ends extending along the Y direction. The ends extending along the Y direction can also be referred to as the ends of the base portion 31 in the X direction. Alternatively, the first housing member 30 may be provided with side walls at the ends in the X direction, which surrounds the first circuit board 10 together with the side walls 32 and 33. As further another example, the first housing member 30 may be provided with a side wall at only one of the ends in the X direction.

The base portion 31 includes a cooling section 31a. The cooling section 31a is a part that forms a hollow section SP3, which will be described later. The facing surface SF32 of the cooling section 31a is provided with a first recess 31b that is recessed more than a peripheral area. The facing surface SF32 of the cooling section 31a is a part that comes into contact with the cooling water CW1.

As shown in FIGS. 2, 5, 6, and the like, the base portion 31 is formed with a first opening 34. The first opening 34 is a through hole that penetrates the base portion 31 from the mounting surface SF31 to the facing surface SF32. The first opening 34 is disposed at a position closer to the side wall 33 than the side wall 32. In the first opening 34, a part of the first connector 14 and second connector 24, which are connected to each other, is disposed.

As shown in FIG. 6, the base portion 31 is provided with a sealing portion 35 around the first opening 34. The sealing portion 35 is provided on the facing surface SF32. The sealing portion 35 is a portion where a connector sealing member 80, which will be described later, is disposed. As an example, the sealing portion 35 has a groove-shape to receive the connector sealing member 80 therein.

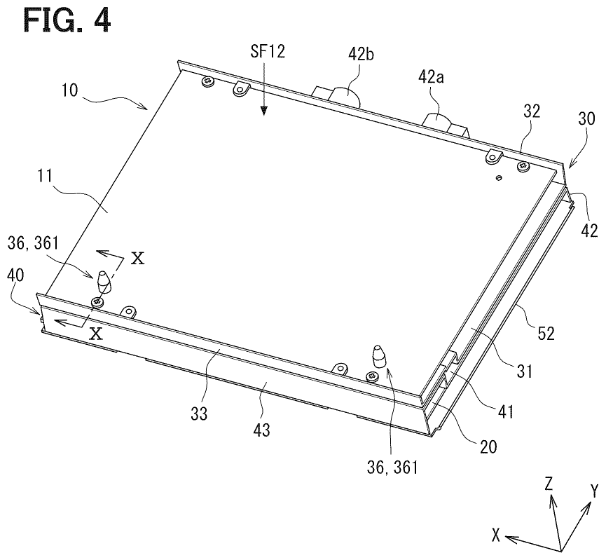

Further, as shown in FIGS. 4, 5, 6 and 10, the first housing member 30 has a first positioning part 36. The first positioning part 36 includes a protrusion 361 that positions the first housing member 30 and the first circuit board 10, and a recess 362 that positions the first housing member 30 and the second housing member 40. The first positioning part 36 is provided integrally with the base portion 31. Alternatively, the first positioning part 36 may be provided separately from the base portion 31. FIG. 10 is a cross-sectional view taken along a line X-X in FIG. 4. In FIG. 10, screws and the like are omitted for the sake of simplicity.

In the present embodiment, as an example, the first housing member 30 having the first positioning parts 36 at two locations is adopted. In other words, the first housing member 30 has two first positioning parts 36. However, the first housing member 30 may have only one first positioning part 36, or may have three or more first positioning parts 36.

As shown in FIG. 5, the protrusion 361 is provided on the mounting surface SF31. The protrusion 361 is a portion that protrudes more than the surrounding area. Therefore, the protrusion 361 is provided so as to protrude from the mounting surface SF31. The protrusion 361 extends along the Z direction. The protrusion 361 is a rod-shaped portion. The protrusion 361 can also be referred to as a positioning pin. The protrusion 361 corresponds to a first board positioning portion.

As shown in FIGS. 5 and 10, the protrusion 361 has, for example, a cylindrical shape. Therefore, the protrusion 361 has a circular cross-sectional shape. The cross-sectional shape is the shape in a cross section parallel to the XY plane. In other words, the protrusion 361 has a portion with a cylindrical shape.

The protrusion 361 is inserted into the positioning hole 15. That is, in the electronic device 100, when the first circuit board 10 is attached to the first housing member 30, the protrusion 361 is inserted into the positioning hole 15. Therefore, it is preferable that the protrusion 361 has an inclined portion 363 at the end. In other words, the cross-sectional area of the protrusion 361 narrows toward the tip. Moreover, it can be said that the protrusion 361 has a tapered end. In this case, the protrusion 361 can be more easily into the positioning hole 15. However, it is not always necessary that the protrusion 361 has the inclined portion 363.

Furthermore, as shown in FIG. 10, it is preferable that the tip portion 36t of the protrusion 361 is located higher than the side wall 33 (i.e., the end 33t of the side wall 33, hereinafter simply referred to as the side wall end 33t). In other words, the tip portion 36t of the protrusion 361 protrudes more than the side wall end 33t. Similarly, it is preferable that the tip portion 36t of the protrusion 361 is located higher than the side wall 32.

As a result, when the first circuit board 10 is assembled to the first housing member 30, the first circuit board 10 is positioned adjacent to the side wall 33 with the protrusion 361 inserted into the positioning hole 15. This makes it easier to insert the protrusion 361 into the positioning hole 15. However, it is not always necessary that the tip portion 36t is located higher than the side wall 33. In this case, the adjacent positions of the first circuit board 10 and the side wall 33 refer to positions facing each other in the Y direction. The tip portion 36t corresponds to a first tip portion.

As shown in FIGS. 6 and 10, the recess 362 is provided in the facing surface SF32. In other words, the recess 362 is provided on the surface opposite to the protrusion 361. The recess 362 is a portion that is recessed from the surrounding area. Therefore, the recess 362 is recessed with respect to the facing surface SF32. The recess 362 is a bottomed hole.

The recess 362 is a portion that engages with a protrusion 462, which will be described later. Therefore, the recess 362 has a shape corresponding to the protrusion 462. The recess 362 and the protrusion 462 are fitted together, for example, as an example of engagement. However, the recess 362 may simply receive the protrusion 462 therein. In the present embodiment, as an example, the recess 362 has a circular shape. The recess 362 can also be referred to as a positioning recess. The recess 362 corresponds to a first housing positioning portion.

Next, the second housing member 40 will be described with reference to FIGS. 2, 3, and 7 to 9. As shown in FIGS. 2, 3 and 7, the second housing member 40 is a member that accommodates the second circuit board 20. It can be said that the second housing member 40 is a member on which the second circuit board 20 is mounted. Therefore, the second housing member 40 can also be referred to as a mounted member or a second mounted member. Further, the second housing member 40 is disposed between the first circuit board 10 and the second circuit board 20, and the second circuit board 20 is attached to the second housing member 40.

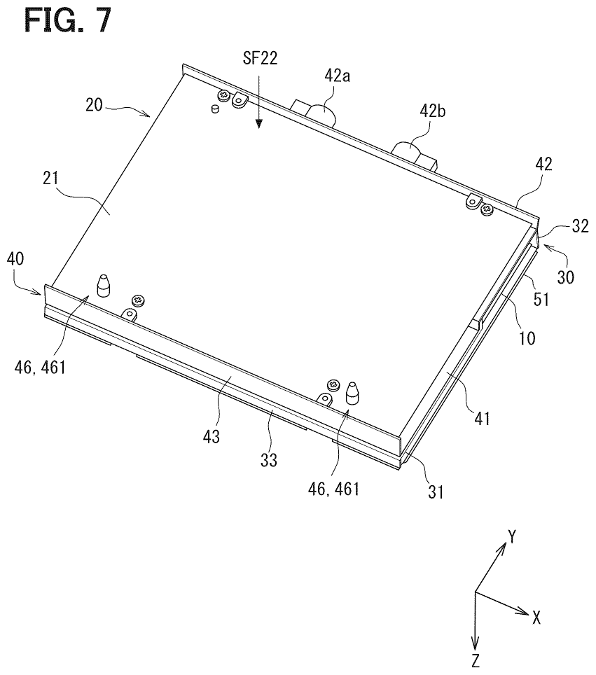

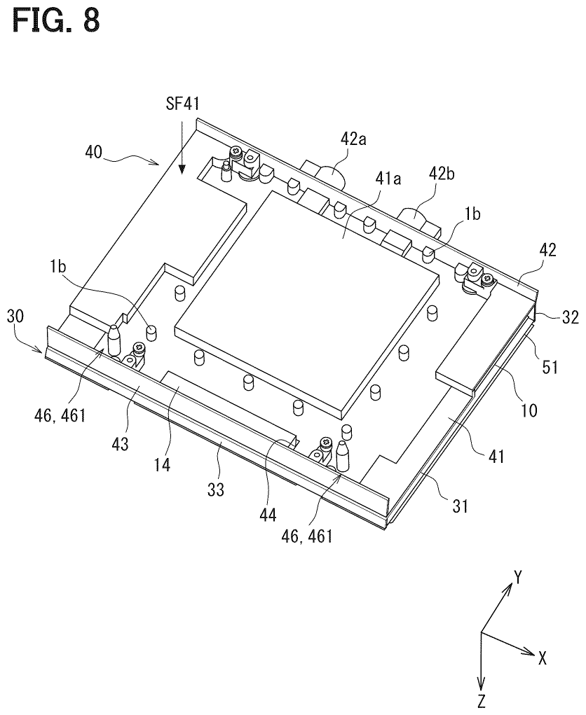

As shown in FIGS. 7 and 8, the second housing member 40 includes a base portion 41 and side walls 42 and 43. The base portion 41 has a mounting surface SF41 on which the second circuit board 20 is mounted, and a facing surface SF42 which is the surface opposite to the mounting surface SF41. The facing surface SF42 is a surface that faces the first housing member 30 when the first housing member 30 and the second housing member 40 are attached to each other. The side walls 42 and 43 correspond to second side walls.

The base portion 41 has side walls 42 and 43 at both ends in the Y direction. The side walls 42 and 43 are provided to protrude in the Z direction from the base portion 41. The side walls 42 and 43 are provided to extend along the X direction. The second housing member 40 has a second accommodation section SP2 that accommodates the second circuit board 20 in an area provided between the side walls 42 and 43. The second accommodation section SP2 is a facing area of the mounting surface SF41 and is an area between the side walls 42 and 43. In addition, it can be said that the second housing member 40 has the side walls 42 and 43 that are disposed on a periphery of the second circuit board 20 when the second circuit board 20 is accommodated therein. As shown in FIG. 10, the tip portion of the side wall 43 is also referred to as a side wall end 43t.

In addition, when the second circuit board 20 is accommodated in the second housing member 40, the mounting surface SF21 faces the mounting surface SF41. On the other hand, the back surface SF22 is exposed. Therefore, the second cover 52 is attached to the second housing member 40 in the facing area of the mounting surface SF41. In other words, the second cover 52 is attached to the second housing member 40 so as to cover the back surface SF22.

Furthermore, the third cover 53 and the fourth cover 54 are attached to the ends of the base portion 41 of the second housing member 40, the ends extending along the Y direction. In this manner, the third cover 53 and the fourth cover 54 are provided to be shared by the first housing member 30 and the second housing member 40. However, in the present disclosure, the third cover 53 and the fourth cover 54 may not be provided. In addition, in the present disclosure, electrical components such as external connection connectors may be attached in place of the third cover 53 and the fourth cover 54.

Further, the second housing member 40 may be provided with side walls at the ends in the X direction, which surrounds the second circuit board 20 together with the side walls 42 and 43. Furthermore, the second housing member 40 may be provided with a side wall on only one of the ends in the X direction.

The base portion 41 includes a cooling section 41a. The cooling section 41a is a part that forms a hollow section SP3, which will be described later. In other words, the cooling section 41a is a part that forms the hollow section SP3 together with the cooling section 31a. The facing surface SF42 of the cooling section 41a is provided with a second recess 41b that is recessed more than the surrounding area. The facing surface SF42 of the cooling section 41a is a part that comes into contact with the cooling water CW1.

In this manner, the hollow section SP3 is formed by the first recess 31b and the second recess 41b facing each other. Therefore, the electronic device 100 can have a hollow section SP3 that is larger than a hollow portion in which either the first recess 31b or the second recess 41b is formed by a flat surface. As such, the electronic device 100 can increase the amount of the cooling water CW1. Accordingly, the electronic device 100 can efficiently cool the circuit boards 10 and 20.

As shown in FIGS. 2, 8, 9, and the like, the base portion 41 is formed with a second opening 44. The second opening 44 is a through hole that penetrates the base portion 41 from the mounting surface SF41 to the facing surface SF42. The second opening 44 is provided at a position closer to the side wall 43 than the side wall 42. In the second opening 44, a part of the first connector 14 and second connector 24, which are connected to each other, is disposed.

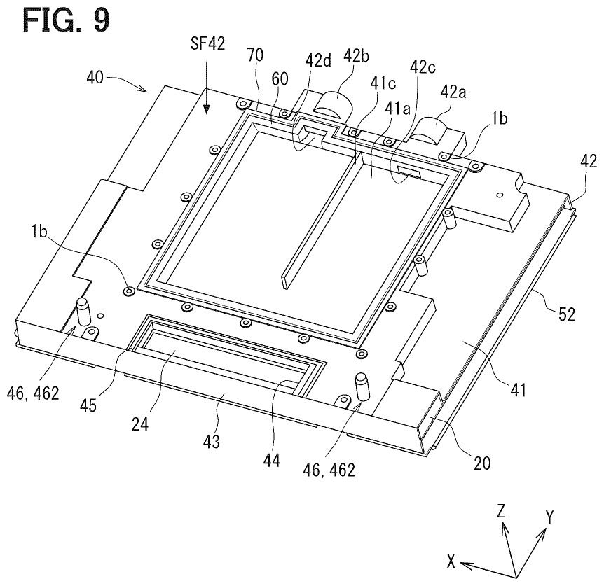

As shown in FIG. 9, the base portion 41 has a sealing portion 45 around the second opening 44. The sealing portion 45 is provided on the facing surface SF42. The sealing portion 45 is a portion where a connector sealing member 80, which will be described later, is disposed. As an example, the sealing portion 45 has a groove shape to receive the connector sealing member 80 therein.

Furthermore, as shown in FIG. 9, the second housing member 40 is provided with an outlet portion 42a and an inlet portion 42b which connect to the side wall 42. The outlet portion 42a and the inlet portion 42b are provided integrally with the side wall 42. Therefore, it can be said that the outlet portion 42a and the inlet portion 42b are provided adjacent to each other on the same side wall 42.

The outlet portion 42a is a portion to which an outlet pipe through which the cooling water CW1 flows is attached. The outlet portion 42a is formed with an outlet port 42c which is a through hole in communication with the hollow section SP3. The cooling water CW1 flowing through the hollow section SP3 passes through the outlet port 42c and is discharged into the outlet pipe.

The inlet portion 42b is a portion to which an inlet pipe through which the cooling water CW1 flows is attached. The inlet portion 42b is formed with an inlet port 42d which is a through hole in communication with the hollow section SP3. The cooling water CW1 is supplied from the inflow pipe through the inlet port 42d into the hollow section SP3.

The second housing member 40 also has a wall portion 41c that protrudes into the hollow section SP3. The wall portion 41c is a portion of the cooling portion 41a that protrudes with respect to the facing surface SF42. The wall portion 41c has a height, for example, approximately equal to the depth of the second recess 41b. However, the wall portion 41c may have a height approximately equal to the depth of the hollow section SP3 in the Z direction. The height is the length in the Z direction. The length of the hollow section SP3 corresponds to the distance between the facing surfaces SF32 and SF42 in the hollow section SP3.

The wall portion 41c is disposed between the outlet port 42c and the inlet port 42d. In other words, the wall portion 41c is connected to a wall of the second recess 41b on the side wall 42 side at a position between the outlet port 42c and the inlet port 42d. The wall portion 41c is extended along the Y direction without reaching a wall of the second recess 41b on the side wall 43. In this manner, the wall portion 41c partially divides the hollow section SP3 into a section on the outlet port 42c side and a section on the inlet port 42d side. This wall portion 41c may be provided on at least one of the first housing member 30 or the second housing member 40. The wall portion 41c can also be referred to as a streamline portion or a streamline wall that organizes the flow of the liquid refrigerant.

The outlet port 42c and the inlet port 42d correspond to an inlet and outlet port. The outlet pipe and the inlet pipe correspond to pipes. It can also be said that the outlet pipe is attached to the outlet port 42c. It can also be said that the inlet pipe is attached to the inlet port 42d.

In the present embodiment, as an example, a configuration in which the second housing member 40 is provided with the outlet portion 42a and the inlet portion 42b is adopted. As another example, the outlet portion 42a and the inlet portion 42b may be provided in the first housing member 30. As further another example, the outlet portion 42a may be provided on one of the first housing member 30 or the second housing member 40, and the inlet portion 42b may be provided on the other.

As still another example, one of the outlet portion 42a and the inlet portion 42b may be provided on the side wall 42, and the other may be provided on the side wall 43. In other words, the electronic device 100 may be configured so that the coolant CW1 flows linearly.

As shown in FIGS. 7, 8, 9 and 10, the second housing member 40 is provided with a second positioning part 46. The second positioning part 46 includes a protrusion 461 that positions the second housing member 40 and the second circuit board 20, and a protrusion 462 that positions the first housing member 30 and the second housing member 40. The protrusion 461 will be also referred to as a first protrusion and the protrusion 462 will be also referred to as a second protrusion 462. The second positioning part 46 is provided integrally with the base portion 41. Alternatively, the second positioning part 46 may be provided separately from the base portion 41.

In the present embodiment, as an example, the second housing member 40 has the second positioning parts 46 at two locations. In other words, the second housing member 40 has two second positioning parts 46. However, the second housing member 40 may have only one second positioning part 46, or may have three or more second positioning parts 46.

As shown in FIG. 8, the protrusion 461 is provided on the mounting surface SF41. The protrusion 461 is a portion that protruded more than the surrounding area. Therefore, the protrusion 461 is provided so as to protrude from the mounting surface SF41. The protrusion 461 extends along the Z direction. The protrusion 461 is a rod-shaped portion. The protrusion 461 can also be referred to as a positioning pin. The protrusion 461 corresponds to a second board positioning portion.

As shown in FIGS. 8 and 10, the protrusion 461 has, for example, a cylindrical shape. Therefore, the protrusion 461 has a circular cross-sectional shape. In other words, the protrusion 461 has a portion with a cylindrical shape. The protrusion 461 has, for example, the same shape as the protrusion 361.

The protrusion 461 is inserted into the positioning hole 25. That is, in the electronic device 100, when the second circuit board 20 is attached to the second housing member 40, the protrusion 461 is inserted into the positioning hole 25. Therefore, it is preferable that the protrusion 461 has an inclined portion 463 at the end. In other words, the cross-sectional area of the protrusion 461 narrows toward the tip. Moreover, it can be said that the protrusion 461 has a tapered end. In this case, the protrusion 461 can be more easily inserted into the positioning hole 25. However, it is not always necessary that the protrusion 461 has the inclined portion 463.

As shown in FIG. 10, it is preferable that a tip portion 46t of the protrusion 461 is located higher than the side wall 43 (i.e., the end 43t of the side wall 43, hereinafter simply referred to as the side wall end 43t). In other words, the tip portion 46t of the protrusion 461 protrudes more than the side wall end 43t. In this case, the higher position refers to a position in a case where the portion of the protrusion 461 that is connected to the base portion 41 is located on the ground side, and the tip portion 46t is located on the top side. Similarly, it is preferable that the tip portion 46t of the protrusion 461 is located higher than the side wall 42.

As a result, when the second circuit board 20 is attached to the second housing member 40, the second circuit board 20 is positioned adjacent to the side wall 43 with the protrusion 461 inserted into the positioning hole 25. This makes it easier to insert the protrusion 461 into the positioning hole 25. However, it is not always necessary that the tip portion 46t is located higher than the side wall 43. In this case, the adjacent positions of the second circuit board 20 and the side wall 43 refer to positions facing each other in the Y direction. The tip portion 46t corresponds to a second tip portion.

As shown in FIGS. 9 and 10, the protrusion 462 is provided on the facing surface SF42. In other words, the protrusion 462 is provided on the surface opposite to the surface on which the protrusion 461 is provided. The protrusion 462 is a portion that protrudes from the surrounding area. The protrusion 462 is a portion onto which the recess 362 fits (engages) as described above.

The protrusion 462 has, for example, a cylindrical shape. Therefore, the protrusion 462 has a circular cross-sectional shape. In other words, the protrusion 462 has a portion with a cylindrical shape. The protrusion 462 is inserted into the recess 362. That is, in the electronic device 100, when the first housing member 30 and the second housing member 40 are assembled, the protrusion 462 is inserted into the recess 362. Therefore, it is preferable that the protrusion 462 has an inclined portion at the end. In other words, the cross-sectional area of the protrusion 462 narrows toward the tip. Moreover, it can be said that the protrusion 462 has a tapered end. This makes it easier to insert the protrusion 462 into the recess 362. However, it is not always necessary that the protrusion 462 has the inclined portion. The protrusion 462 corresponds to a second housing positioning portion.

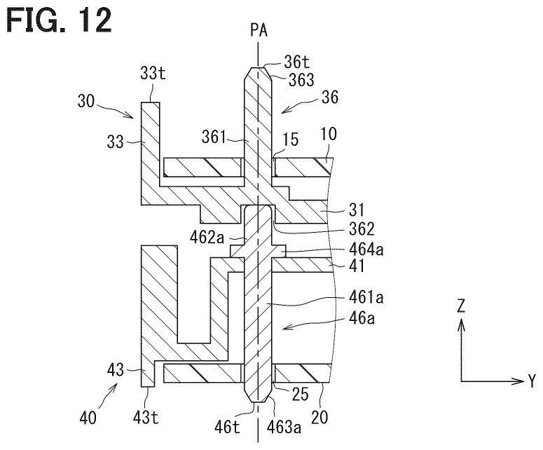

FIG. 12 shows a second positioning part 46a that is provided separately from the base portion 41. Similar to the second positioning part 46 shown in FIG. 10, the second positioning part 46a has a protrusion 461a and a protrusion 462a. The protrusion 461a preferably has an inclined portion 463a. The protrusion 461a has a similar configuration to the protrusion 461. The inclined portion 463a has a similar configuration to the inclined portion 463. The protrusion 462a has the same configuration as the protrusion 462.

In this case, the base portion 41 is formed with a through hole into which the second positioning part 46a is inserted. The second positioning part 46a is provided with a stopper 464a so as to be held on the base portion 41.

This improves the degree of freedom in determining the position to provide the second positioning part 46a on the second housing member 40. For example, the second housing member 40 is molded using a mold or the like. In molding, it may be difficult to provide the second positioning part 46. In the case where the second positioning part 46a is provided as a separate member from the base portion 41, it is sufficient for the base portion 41 to only have the through hole. Furthermore, the second positioning part 46a can be disposed at any position in the base portion 41 where the through hole can be provided. The similar effects can be achieved even when the base portion 31 and the first positioning part 36 are composed of the separate members.

The positioning using the first positioning part 36 and the second positioning part 46 will be described in detail later.

As described above, the electronic device 100 includes, as accommodation sections, the first accommodation section SP1 and the second accommodation section SP2. In addition, the first housing member 30 and the second housing member 40 are provided with the accommodation sections SP1 and SP2. Therefore, the first housing member 30 and the second housing member 40 correspond to an accommodation housing member. However, the present disclosure can also be adopted in a configuration in which the accommodation sections SP1 and SP2 are provided in at least one of the first housing member 30 and the second housing member 40.

The first housing member 30 and the second housing member 40 are made of a metal, such as aluminum, as a main component. However, the present disclosure is not only limited to this example. Only one of the first housing member 30 and the second housing member 40 may be made of a metal as a main component. Alternatively, the first housing member 30 and the second housing member 40 may be made of a resin as a main component.

### Electronic device

The assembling of the components described above and the electronic device 100 in the assembled state will be described hereinafter.

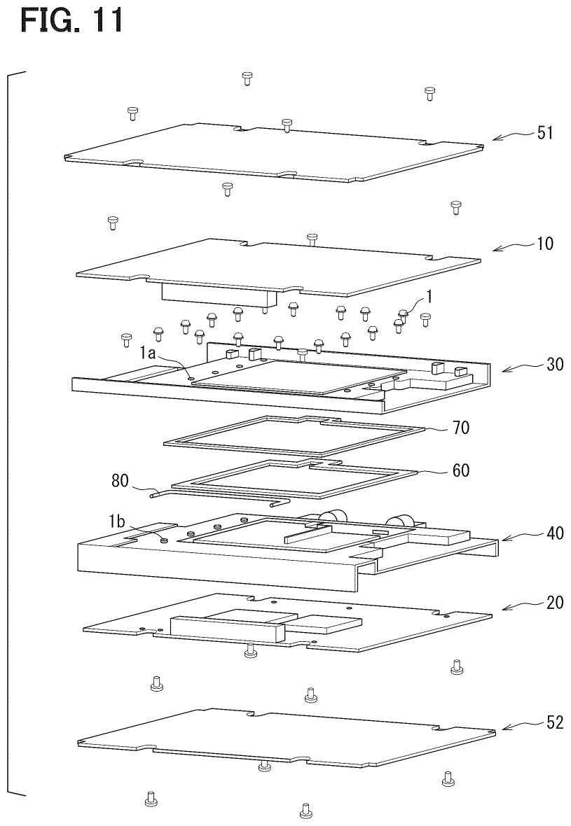

As shown in FIG. 11, the electronic device 100 includes the first circuit board 10, the second circuit board 20, the first housing member 30, the second housing member 40, the first cover 51, and the second cover 52 as separate components. Further, the electronic device 100 includes the sealing member 60, a gasket 70, and the connector sealing member 80 as separate components. In FIG. 11, the positioning parts 36 and 46 are omitted in order to simplify the drawing.

The electronic device 100 is produced by stacking and assembling the first circuit board 10, the second circuit board 20, the first housing member 30, the second housing member 40, the first cover 51, and the second cover 52. The direction in which the first circuit board 10, the second circuit board 20, the first housing member 30, the second housing member 40, the first cover 51, and the second cover 52 are stacked is also referred to as a stacking direction. The stacking direction coincides with the Z direction.

The electronic device 100 is assembled such that the facing surface SF32 of the first housing member 30 and the facing surface SF42 of the second housing member 40 face each other. The first housing member 30 and the second housing member 40 are fixed together by a screw member 1, which is a male screw. As shown in FIG. 6, the first housing member 30 is formed with a screw opening 1a into which the screw member 1 is inserted. The second housing member 40 is formed with a screw hole portion 1b into which the screw member 1 is fastened, as shown in FIG. 9. The screw hole portion 1b is formed with a female thread. The first housing member 30 and the second housing member 40 are fixed together by fastening the screw member 1 into the screw hole portion 1b while the screw member 1 passing through the screw opening portion 1a.

Further, when the first housing member 30 and the second housing member 40 are assembled together, the hollow section SP3 is formed by the facing surfaces SF32 and SF42. The hollow section SP3 defines a space through which the cooling water CW1 flows. Therefore, the hollow section SP3 can also be regarded as a coolant flow path.

As shown in FIGS. 2, 3, 6 and 9, the sealing member 60 is provided between the first housing member 30 and the second housing member 40 so as to surround the entire perimeter of the hollow section SP3. It can also be said that the sealing member 60 is provided in the facing area between the first housing member 30 and the second housing member 40. That is, the first housing member 30 and the second housing member 40 are fixed together with the sealing member 60 disposed in the facing area.

The sealing member 60 is a member for restricting the cooling water CW1 from leaking from the hollow section SP3. The sealing member 60 may be an O-ring, a caulking material, or the like.

The sealing member 60 is in contact with the first housing member 30 and the second housing member 40. More specifically, the sealing member 60 contacts the facing surfaces SF32 and SF42. Furthermore, the sealing member 60 is fixed by the screw member 1 as described above, and is disposed in a pressed state by the facing surfaces SF32 and SF42. Therefore, the electronic device 100 can suppress the cooling water CW1 from leaking from the hollow section SP3.

As shown in FIGS. 6 and 9, the screw members 1 are provided at multiple locations on the outer periphery of the sealing member 60. In other words, the screw members 1 are provided at multiple locations so as to surround the sealing member 60. The screw members 1 are provided at the multiple locations on each side of the sealing member 60 along the Y direction. Further, the screw members 1 are provided at the multiple locations on each side of the sealing member 60 along the X direction. Furthermore, the screw members 1 are provided at two locations interposing the output pot 42c therebetween, and the screw members 1 are provided at two locations interposing the inlet port 42d therebetween.

As such, in the electronic device 100, the sealing member 60 can be pressed by the first housing member 30 and the second housing member 40 along its entire perimeter, improving the sealing performance. In other words, the electronic device 100 can improve a leakage restriction function provided by the sealing member 60.

The electronic device 100 does not necessarily have to include the sealing member 60. For example, by welding the first housing member 30 and the second housing member 40 together so as to surround the entire periphery of the hollow section SP3, it is possible to restrict the cooling water CW1 from leaking from the hollow section SP3.

As shown in FIGS. 2, 3, 6 and 9, the gasket 70 is provided in the facing area between the first housing member 30 and the second housing member 40 so as to surround the entire perimeter of the sealing member 60. It can also be said that the gasket 70 is provided on the outer periphery of the sealing member 60. In other words, the first housing member 30 and the second housing member 40 are fixed together with the gasket 70 disposed in the facing area.

As described above, the electronic device 100 includes the sealing member 60 for restricting the cooling water CW1 from leaking from the hollow section SP3. However, the cooling water CW1 may leak due to deterioration of the sealing member 60 or the like. The gasket 70 is a member for restricting the leaking cooling water CW1 from splashing forcefully even if the cooling water CW1 leaks. The gasket 70 corresponds to a splashing restriction member.

The material of the gasket 70 is not particularly limited. It is preferable that the gasket 70 is in contact with both of the facing surfaces SF32 and SF42. However, it is sufficient that the gasket 70 is in contact with at least one of the facing surfaces SF32 and SF42. Further, the gasket 70 may be employed in a portion that protrudes from at least one of the facing surfaces SF32 and SF42.

As a result, even if the cooling water CW1 leaks from the hollow section SP3, the electronic device 100 can restrict the leaked liquid coolant from flowing out forcefully. The screw members 1 may be provided at multiple locations on the outer periphery of the gasket 70. However, the electronic device 100 does not necessarily have to include the gasket 70.

As described above, the second housing member 40 includes the wall portion 41c. Therefore, when the first housing member 30 and the second housing member 40 are assembled together, the wall portion 41c is located in the hollow section SP3. As a result, the cooling water CW1 flows in a U-shape within the hollow section SP3. Therefore, the electronic device 100 can be configured so that the cooling water CW1 can easily flow throughout the entire hollow section SP3.

More specifically, in the present embodiment, as an example, the configuration in which the inlet port 42d and the outlet port 42c are provided on one of the side walls 42 is adopted. Therefore, the cooling water CW1 flows from the inlet port 42d into the hollow section SP3, flows throughout the entire hollow section SP3, and is easily discharged from the outlet port 42c. This configuration can restrict the cooling water CW1 from stagnating in part of the hollow section SP3. Therefore, the electronic device 100 can have a larger cooling space. However, the electronic device 100 may not include the wall portion 41c.

As shown in FIGS. 2 and 3, a gap SP4 that communicates with the external space is provided on the outer periphery of the sealing member 60 between the facing surfaces SF32 and SF42. In other words, in the electronic device 100, when the first housing member 30 and the second housing member 40 are assembled, the facing surface SF32 and the facing surface SF42 are in a non-contact state on the outer periphery of the sealing member 60. The gap SP4 can be regarded as the facing area between the facing surface SF32 and the facing surface SF42 around the periphery of the sealing member 60.

The external space is a space in which the electronic device 100 is placed. The external space can also be regarded as the space surrounding the electronic device 100. As such, in the electronic device 100, even if the cooling water CW1 leaks from the hollow section SP3, it is possible to release the leaking cooling water CW1 to the external space. However, the electronic device 100 may not have the gap SP4. As an example, the gap SP4 may be provided only in a portion of the periphery of the sealing member 60.

The connector sealing member 80 is provided around the first opening 34 and the second opening 44 between the first housing member 30 and the second housing member 40. In other words, the first housing member 30 and the second housing member 40 are fixed together with the connector sealing member 80 disposed between the sealing portions 35 and 45.

The connector sealing member 80 is in contact with the sealing portions 35 and 45. More specifically, as the first housing member 30 and the second housing member 40 are fixed together by the screw member 1 as described above, the connector sealing member 80 is disposed in a state of being pressed by the sealing portions 35 and 45. As such, the electronic device 100 restricts the first connector 14 and the second connector 24 from becoming wet even if the cooling water CW1 leaks from the hollow section SP3.

In this manner, by fixing the first housing member 30 and the second housing member 40 with the screw member 1, a base part of the housing having the hollow section SP3 and the gap SP4 is formed. As shown in FIGS. 4, 7, and the like, the first circuit board 10 and the second circuit board 20 are mounted on the base part. That is, the first circuit board 10 is mounted on the first housing member 30. The second circuit board 20 is mounted on the second housing member 40. The housing members 30 and 40 and the circuit boards 10 and 20 are fixed together by screws or the like.

As a result, as shown in FIGS. 2 and 3, the first circuit board 10 and the second circuit board 20 are fixed so as to interpose the base portion 31 of the first housing member 30 and the base portion 41 of the second housing member 40 therebetween. Furthermore, the cooling sections 31a and 41a are disposed between the first circuit board 10 and the second circuit board 20. Therefore, the hollow section SP3 is provided between the first circuit board 10 and the second circuit board 20. As such, in the electronic device 100, the first circuit board 10 and the second circuit board 20 can be cooled by the cooling water CW1 flowing through the single hollow section SP3. In other words, the hollow section SP3 can be regarded as a coolant space provided in common to the first circuit board 10 and the second circuit board 20.

Furthermore, it is preferable that the circuit boards 10 and 20 are disposed so that the mounted components 12 and 22 face the cooling sections 31a and 41a, respectively. In this case, the electronic device 100 can efficiently cool the mounted components 12 and 22.

In particular, the electronic device 100 includes the first circuit board 10 and the second circuit board 20. Furthermore, in the electronic device 100, the number of mounted components 12 and 22 and the number of calculations performed by the respective mounted components 12 and 22 may increase as functions are integrated. As a result, the amount of heat generated by the electronic device 100 may increase. In contrast, the electronic device 100 can cool the first circuit board 10 and the second circuit board 20 with the cooling water CW1. Therefore, the electronic device 100 can operate the first circuit board 10 and the second circuit board 20 at appropriate temperatures. In other words, the electronic device 100 can withstand the increases in the number of mounted components 12 and 22 and the number of calculations performed by the respective mounted component 12 and 22. Furthermore, the electronic device 100 can maintain stable operation even if the number of mounted components 12 and 22 and the number of calculations of the respective mounted component 12 and 22 increase.

In the present embodiment, as an example, the electronic device 100 employs the first housing member 30 and the second housing member 40 that are made of metal as a main component. Therefore, the electronic device 100 can improve the cooling effect of the circuit boards 10 and 20 by the cooling water CW1.

However, the present disclosure is not only limited to the example illustrated. Only one of the first housing member 30 and the second housing member 40 may be made of metal as a main component. In a configuration in which a circuit board is mounted on only one of the first housing member 30 and the second housing member 40, it is preferable that the one on which the circuit board is mounted is made of metal as a main component. In other words, it is preferable that either the first housing member 30 or the second housing member 40 in which the accommodation section SP1, SP2 is formed is made of metal as a main component. As such, the electronic device 100 can improve the cooling effect of the cooling water CW1 on the circuit board.

The first housing member 30 has the two side walls 32 and 33 that provide the first accommodation section SP1 therebetween. Similarly, the second housing member 40 has the two side walls 42 and 43 that provide the second accommodation section SP2 therebetween. Therefore, even if the cooling water CW1 leaks from the hollow section SP3, the electronic device 100 can restrict the cooling water CW1 from entering the accommodation sections SP1 and SP2.

Pipes through which the cooling water CW1 flows are attached to the outlet portion 42a and the inlet portion 42b. Therefore, there is a possibility that the cooling water CW1 may flow out from the attachment portions between the outlet portion 42a and the inlet portion 42b and the pipes.

However, as shown in FIGS. 2, 7, and the like, the second housing member 40 has the side wall 42 between the second accommodation section SP2 and the outlet portion 42a and inlet portion 42b. Similarly, as shown in FIGS. 2, 4, and the like, the first housing member 30 has the side wall 32 between the first accommodation section SP1 and the outlet portion 42a and inlet portion 42b. In other words, the side wall 32 separates the outlet portion 42a and the inlet portion 42b from the first accommodation section SP1. The side wall 42 separates the outlet portion 42a and the inlet portion 42b from the second accommodation section SP2. Therefore, the electronic device 100 can restrict the cooling water CW1 leaking from the attachment portions between the outlet portion 42a and the inlet portion 42b and the pipes from reaching the circuit boards 10 and 20.

### Positioning

Here, positioning using the first positioning part 36 and the second positioning part 46 will be described with reference to FIG. 10. The positioning parts 36 and 46 are components that position the housing members 30 and 40 relative to each other, while also positioning the circuit boards 10 and 20 relative to each other.

The protrusion 361, the recess 362, the protrusion 461 and the protrusion 462 are provided on the same positioning axis PA. The positioning axis PA is an imaginary straight line extending along the stacking direction. Therefore, it can be said that the protrusion 361, the recess 362, the protrusion 461, and the protrusion 462 are located on the same straight line. Moreover, it can be said that the central axis of the protrusion 361, the central axis of the recess 362, the central axis of the protrusion 461, and the central axis of the protrusion 462 are aligned on the same straight line. The central axis is an imaginary axis along the Z direction. Furthermore, it can be said that the protrusion 361, the recess 362, the protrusion 461, and the protrusion 462 coincide with each other in positions in the X direction and in positions in the Y direction.

The electronic device 100 is produced by stacking and assembling the components as described above. The first housing member 30 and the second housing member 40 are assembled so that the facing surfaces SF32 and SF42 face each other. At this time, the protrusion 462 is inserted into the recess 362. As a result, the first housing member 30 and the second housing member 40 are positioned relative to each other.

Moreover, the first circuit board 10 and the first housing member 30 are assembled so that the mounting surface SF11 and the mounting surface SF31 face each other. At this time, the protrusion 361 is inserted into the positioning hole 15. As a result, the first circuit board 10 and the first housing member 30 are positioned relative to each other.

The second circuit board 20 and the second housing member 40 are assembled so that the mounting surface SF21 and the mounting surface SF41 face each other. At this time, the protrusion 461 is inserted into the positioning hole 25. As a result, the second circuit board 20 and the second housing member 40 are positioned relative to each other.

In this manner, in the electronic device 100, the first housing member 30 and the second housing member 40 are positioned relative to each other. Further, in the first housing member 30 and the second housing member 40 positioned relative to each other, the first circuit board 10 is positioned relative to the first housing member 30 and the second circuit board 20 is positioned relative to the second housing member 40. Thus, the first circuit board 10 and the second circuit board 20 are positioned by the first positioning part 36 and the second positioning part 46, respectively.

The first circuit board 10, the first housing member 30, the second housing member 40, and the second circuit board 20 are assembled in the positioned state as described above. Therefore, the first connector 14 and the second connector 24 are connected to each other in such an assembled state.

In addition, the first connector 14 is mounted on the first circuit board 10. On the other hand, the second connector 24 is mounted on the second circuit board 20. The first circuit board 10 and the second circuit board 20 are positioned as described above. Therefore, the first connector 14 and the second connector 24 are connected to each other in the positioned state.

The first connector 14 and the second connector 24 are positioned by the first positioning part 36 and the second positioning part 46. Therefore, it is preferable that the first positioning part 36 positions the first housing member 30 and the first circuit board 10 relative to each other, and the second positioning part 46 positions the second housing member 40 and the second circuit board 20 relative to each other, before the first connector 14 and the second connector 24 are connected. In other words, it is preferable that the protrusion 361 of the first positioning part 36 is inserted into the positioning hole 15 and the protrusion 461 of the second positioning part 46 is inserted into the positioning hole 25 before the first connector 14 and the second connector 24 are connected to each other.

The position of the first circuit board 10 in the Z direction is determined by the position of a base provided on the mounting surface SF31 of the first housing member 30. On the other hand, the position of the second circuit board 20 in the Z direction is determined by the position of a base provided on the mounting surface SF41 of the second housing member 40.

### Effects

As described above, the electronic device 100 includes the first positioning part 36 having the protrusion 361 and the recess 362, and the second positioning part 46 having the protrusion 461 and the protrusion 462. Therefore, the electronic device 100 can position the first housing member 30 and the first circuit board 10 relative to each other, the first housing member 30 and the second housing member 40 relative to each other, and the second housing member 40 and the second circuit board 20 relative to each other. In other words, the electronic device 100 can position the first circuit board 10 and the second circuit board 20.

In the electronic device 100, the protrusion 361, the recess 362, the protrusion 461, and the protrusion 462 are provided on the same straight line. Therefore, the electronic device 100 can minimize the accumulation of tolerances thereof. As such, the electronic device 100 can position the first circuit board 10 and the second circuit board 20 with high accuracy. In other words, the electronic device 100 can position the first circuit board 10 and second circuit board 20 with higher accuracy than a configuration in which the protrusion 361, the recess 362, the protrusion 461, and the protrusion 462 are not arranged on the same straight line.

In the electronic device 100, the first connector 14 is mounted on the first circuit board 10, and the second connector 24 is mounted on the second circuit board 20. Therefore, the electronic device 100 can position the first connector 14 and the second connector 24 with high accuracy. As such, the electronic device 100 can connect the first connector 14 and the second connector 24 in a state of being positioned with high accuracy. Accordingly, the electronic device 100 can reduce the load on the first connector 14 and the second connector 24, as compared to a configuration in which the positioning accuracy between the first connector 14 and the second connector 24 is not high. In other words, the load applied to both the first and second connectors 14 and 24 due to misalignment between the first connector 14 and the second connector 24 can be reduced.

In the electronic device 100, the accommodation sections SP1 and SP2 in which the circuit boards 10 and 20 are accommodated and the hollow section SP3 through which the cooling water CW1 flows are separated by the first housing member 30 and the second housing member 40. In other words, the accommodation sections SP1 and SP2 and the hollow section SP3 are partitioned by at least the base portions 31 and 41. Further, the accommodation sections SP1 and SP2 and the hollow section SP3 are separate spaces.

Therefore, even if the cooling water CW1 leaks from the hollow section SP3, the electronic device 100 can restricts the cooling water CW1 from entering the accommodation sections SP1 and SP2. In other words, the electronic device 100 can restrict the circuit boards 10 and 20 from becoming wet.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. An electronic device comprising:
a first circuit board;
a second circuit board;
a first housing member disposed between the first circuit board and the second circuit board and to which the first circuit board is attached; and
a second housing member disposed between the first circuit board and the second circuit board and to which the first housing member and the second circuit board are attached, wherein
the first housing member includes a first positioning part,
the first positioning part has a first board positioning portion that positions the first housing member and the first circuit board, and a first housing positioning portion that positions the first housing member and the second housing member,
the second housing member includes a second positioning part,
the second positioning part has a second board positioning portion that positions the second housing member and the second circuit board, and a second housing positioning portion that engages with the first housing positioning portion to position the first housing member and the second housing member, and
the first board positioning portion, the first housing positioning portion, the second board positioning portion, and the second housing positioning portion are arranged on a same straight line.

2. The electronic device according to claim 1, wherein
at least one of the first positioning part or the second positioning part is composed of a separate member from a base portion of a corresponding one of the first housing member or the second housing member.

3. The electronic device according to claim 1, wherein
the first positioning part and a base portion of the first housing member are composed of an integral member, and
the second positioning part and a base portion of the second housing member are composed of an integral member.

4. The electronic device according to claim 1, wherein
at least one of the first board positioning portion, the second board positioning portion, or the second housing positioning portion has a shape that protrudes from a peripheral area thereof and has a circular cross-sectional shape.

5. The electronic device according to claim 1, wherein
the first housing member has two of the first positioning parts, and
the second housing member has two of the second positioning parts.

6. The electronic device according to claim 1, wherein
the first circuit board includes a first connector, and
the second circuit board includes a second connector connected to the first connector.

7. The electronic device according to claim 1, wherein
the first housing member has a first side wall disposed on a periphery of the first circuit board, and
the first board positioning portion has a tip portion at a position higher than the first side wall.

8. The electronic device according to claim 1, wherein
the second housing member has a second side wall disposed on a periphery of the second circuit board, and
the second board positioning portion has a tip portion at a position higher than the second side wall.

9. The electronic device according to claim 6, wherein
the first positioning part and the second positioning part are configured to enable the first housing member and the first circuit board to be positioned relative to each other and the second housing member and the second circuit board to be positioned relative to each other, before the first connector and the second connector are connected to each other.
